(19) United States
(12) Patent Application Publication
(10) Pub. No.: US 2002/0158318 A1
(43) Pub. Date: Oct. 31, 2002

(54) Multi-chip module

(76) Inventor: Hung Nan Chen, Kaohsiung (TW)

Correspondence Address: DYKEMA GOSSETT PLLC, FRANKLIN SQUARE, THIRD FLOOR WEST, 1300 I STREET, NW, WASHINGTON, DC, 20005, US

(21) Appl. No.: 09/841,075

(22) Filed: Apr. 25, 2001

(51) Int. Cl. H01L 23/02

(52) U.S. Cl. 257/678

(57) ABSTRACT

A multi-chip module mainly comprises an upper chip mounted on an interconnection substrate and a lower chip mounted inside a cavity formed on a base substrate wherein the interconnection substrate is disposed on the upper surface of the base substrate. The base substrate includes a first set of contacts formed inside the cavity, a second set of contacts on the upper surface of the base substrate outside the cavity, and a third set of contacts on the lower surface of the base substrate wherein the third set of contacts are electrically interconnected to the first set of contacts and the second set of contacts. The lower chip inside the cavity of the base substrate is electrically connected to the first set of contacts and encapsulated in a first package body forming a maximum profile height. The interconnection substrate is provided with a set of interconnection pads on a lower surface thereof for electrically interconnecting to the second set of contacts. The upper chip is mounted on the upper surface of the interconnection substrate and electrically connected to the set of interconnection pads. A second package body encapsulates the upper chip.

### BACKGROUND OF THE INVENTION

1. Field of the Invention

This invention relates to a multi-chip module (MCM), and more specifically to a MCM having a stacking arrangement.

2. Description of the Related Art

As electronic devices have become more smaller and thinner, the packages for protecting and interconnecting IC chips have the same trend, too.

With ever increasing demands for miniaturization and higher operating speeds, multi-chip modules (MCMs) are increasingly attractive in a variety of electronics. MCMs that contain more than one chip can help minimize the system operational speed restrictions imposed by long printed circuit board connection traces by combining, for example, the processor, memory, and associated logic into a single package. In addition, MCMs decrease the interconnection length between IC chips thereby reducing signal delays and access times.

The most common MCM is the “side-by-side” MCM. In this version two or more IC chips are mounted next to each other (or side by side each other) on the principal mounting surface of a common substrate. Interconnections among the chips and conductive traces on the substrate are commonly made via wire bonding. The side-by-side MCM, however, suffers from a disadvantage that the package efficiency is very low since the area of the common substrate increases with an increase in the number of semiconductor chips mounted thereon.

Therefore, the semiconductor industry develops a stacked chip package 100 (see FIG. 1) comprising two chips 110, 130 stacked each other. The chip 110 is attached onto the upper surface of a substrate 150 through an adhesive layer 112. An adhesive layer 132 is interposed between the chips 110, 130. The chips 110, 130 are respectively connected to wire bondable pads 152 on the upper surface of the substrate 150 through bonding wires 114, 134. The lower surface of the substrate 150 is provided with a plurality of solder pads 154 electrically connected to the wire bondable pads 152 on the upper surface of the substrate 150. Each solder pad 154 is provided with a solder ball 156 for making external electrical connection. A package body 160 encapsulates the chips 110, 130, the bonding wires 114, 134 and a portion of the upper of the substrate 150. However, the upper chip 130 will interfere wire-bonding operation of the lower chip 110 when the upper chip 130 has a size close to the size of the lower chip 110. Moreover, comparing to the bonding wires 114 for chip 110, the bonding wires 134 for chip 130 have a much longer wire length and a much higher loop height thereby increasing the difficulty encountered in the wire bonding operation thereof. For example, longer wire with higher loop profile is more prone to break during wire bonding operation and to have problems of wire sweeping during encapsulation. Further, it requires a much thicker package body for stacked chip packages to encapsulate the stacked chips as well as bonding wires having a much longer wire length and a much higher loop height thereby reducing the packaging efficiency.

In addition, one problem with placing multiple chips within a single package is with additional chip, additional possible defects are possible within the package. One of the defects is originated from known good die (KGD). Until the chip is wire bonded to the substrate and is tested, it is generally difficult to determine whether the chip is defective. If one chip within a MCM is defective, the entire package must then be discarded. Thus, although MCM have provided increased functionality, yields have decreased as a result of the increased chances for defects.

### SUMMARY OF THE INVENTION

It is an object of the present invention to provide an improved method and apparatus for placing multiple chips in a chip package.

It is another object of the present invention to provide a multi-chip module having a low profile capable of overcoming, or at least reducing the above-mentioned problems of prior arts.

The multi-chip module in accordance with the present invention mainly comprises an upper chip mounted on an interconnection substrate and a lower chip mounted inside a cavity formed on a base substrate wherein the interconnection substrate is disposed on the upper surface of the base substrate. The base substrate includes a first set of contacts formed inside the cavity, a second set of contacts on the upper surface of the base substrate outside the cavity, and a third set of contacts on the lower surface of the base substrate wherein the third set of contacts are electrically interconnected to the first set of contacts and the second set of contacts. The lower chip inside the cavity of the base substrate is electrically connected to the first set of contacts wherein the first semiconductor chip is encapsulated in a first package body forming a maximum profile height. The interconnection substrate is provided with a set of interconnection pads on a lower surface thereof for electrically interconnecting to the second set of contacts. The upper chip is mounted on the upper surface of the interconnection substrate and electrically connected to the set of interconnection pads. A second package body encapsulates the upper chip.

It is noted that the upper chip and the lower chip are packaged and tested separately before mounting the interconnection substrate to the base substrate. Therefore, the need for known good die (KGD) to manufacture the multi-chip module can be avoided, and the difficulties in performing test at the MCM level are greatly reduced, thereby significantly increasing resulting yield of the MCM in accordance with the present invention. Also, the interconnection substrate is mounted on the upper surface of the base substrate in a manner that the minimum distance between the interconnection substrate and the cavity is greater than the maximum profile height of the first package body, thereby obtaining a multi-chip module having a low profile.

### BRIEF DESCRIPTION OF THE DRAWINGS

Other objects, advantages, and novel features of the invention will become more apparent from the following detailed description when taken in conjunction with the accompanying drawings.

FIG. 1 is a cross sectional view of a conventional stacked chip package;

FIG. 2 is a cross sectional view of a multi-chip module according to a first preferred embodiment of the present invention;

FIG. 3 is a cross sectional view of a multi-chip module according to a second preferred embodiment of the present invention;

FIG. 4 is a cross sectional view of a multi-chip module according to a third preferred embodiment of the present invention;

FIG. 5 is a cross sectional view of a multi-chip module according to a fourth preferred embodiment of the present invention;

FIG. 6 is a cross sectional view of a multi-chip module according to a fifth preferred embodiment of the present invention; and

FIG. 7 is a cross sectional view of a multi-chip module according to a sixth preferred embodiment of the present invention.

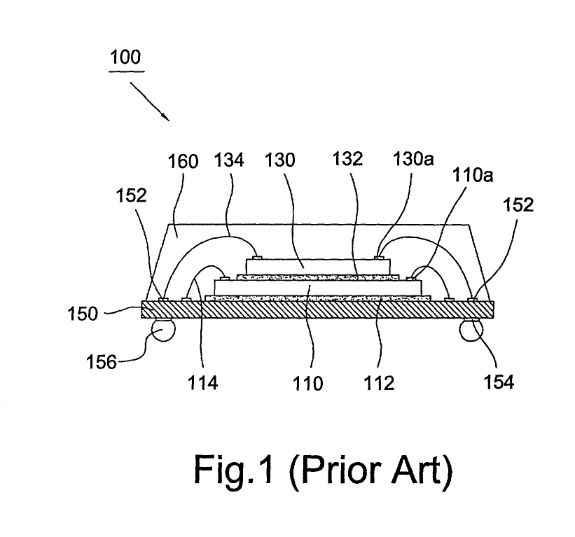

### DETAILED DESCRIPTION OF THE PREFERRED EMBODIMENT

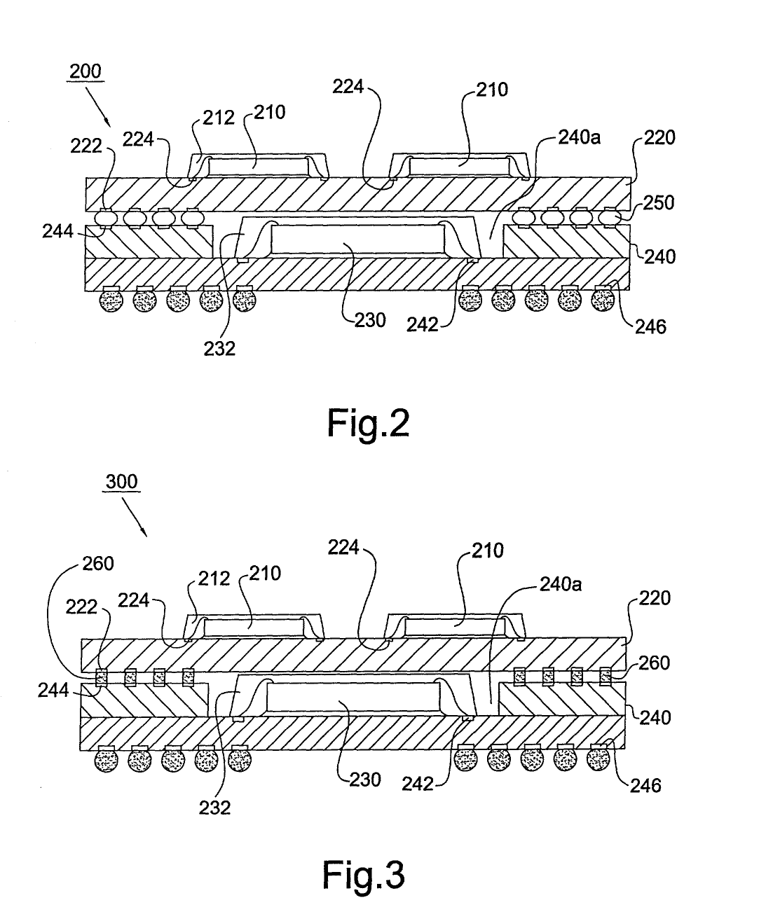

FIG. 2 shows a multi-chip module 200 according to a first preferred embodiment of the present invention. The multi-chip module 200 mainly comprises two upper chips 210 mounted on an interconnection substrate 220 and a lower chip 230 mounted inside a cavity 240a formed on a base substrate 240. The base substrate 240 includes a first set of contacts 242 formed inside the cavity 240a, a second set of contacts 244 on the upper surface of the base substrate 240 outside the cavity 240a, and a third set of contacts 246 on the lower surface of the base substrate 240. It could be understood that the base substrate 240 has a plurality of electrically conductive lines (not shown) for providing electrical connection between the first set of contacts 242, the second set of contacts 244, and the third set of contacts 246. The interconnection substrate 220 includes a set of interconnection pads 222 formed on the lower surface thereof and two sets of interconnection pads 224 formed on the upper surface thereof. It could be understood that the interconnection substrate 220 has a plurality of electrically conductive lines (not shown) for providing electrical connection between the interconnection pads 222 and the interconnection pads 224. The substrate in accordance with the present invention may be formed from a core layer made of fiberglass reinforced BT (bismaleimide-triazine) resin or FR-4 fiberglass reinforced epoxy resin. Alternatively, the substrate may be a ceramic substrate.

First, the chip 230 is mounted inside the cavity 240a on the base substrate 240 by a die attach material, and then, bond wires, for example, gold wires, are bonded by wire bonding machines (not shown) to connect bonding pads on the chip 230 to the first set of contact pads 242. Thereafter, the chip 230 is sealed in a package body 232 by a conventional transfer-molding process. Alternatively, the package body may be formed by a glob-top process.

Next, the chips 210 are securely attached onto the upper surface of the interconnection substrate 220, and bond wires, for example, gold wires, are connected to bonding pads on each chip 210 and the interconnection pads 224. Then, each chip 210 is sealed in a package body 212. It could be understood that the chip 210 or the chip 230 may be electrically interconnected to the conductive lines of substrate by other conventional techniques such as flip-chip or TAB (Tape Automated bonding).

Preferably, the upper chips 210 and the lower chip 230 are packaged and tested separately before mounting the interconnection substrate 220 to the base substrate 240. It is noted that the interconnection substrate 220 is mounted on the upper surface of the base substrate 240 in a manner that the minimum distance between the interconnection substrate 220 and the cavity 240a is greater than the maximum profile height of the package body 232, thereby obtaining a multi-chip module having a low profile. As shown in FIG. 2, the interconnection pads 222 on the lower surface of the interconnection substrate 220 are attached to the second set of contacts 244 on the upper surface of the base substrate 240 through a plurality of solder balls 250.

FIG. 3 shows a multi-chip module 300 according to a second preferred embodiment of the present invention. The multi-chip module 300 is characterized in that the interconnection pads 222 on the lower surface of the interconnection substrate 220 is electrically interconnecting to the second set of contacts 244 on the upper surface of the base substrate 240 through column-like solder bumps 260. Preferably, the column-like solder bumps 260 are formed from stencil-printing.

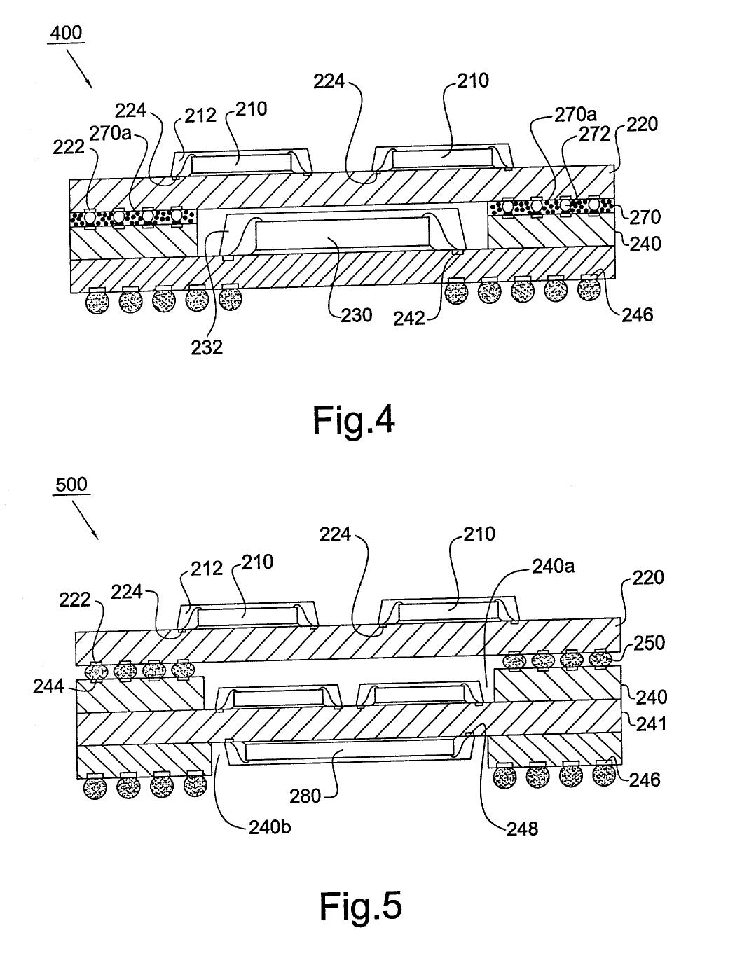

FIG. 4 shows a multi-chip module 400 according to a third preferred embodiment of the present invention. The multi-chip module 400 is characterized in that the interconnection substrate 220 is attached onto the upper surface of the base substrate 240 through an anisotropic conductive adhesive film (ACF) 270. The interconnection pads 222 on the lower surface of the interconnection substrate 220 are provided with a plurality of metal bumps 272. Preferably, the metal bumps 272 are stud bumps formed from conventional wire bonding techniques. It could be understood that the metal bumps 272 may be provided on the second set of contacts 244 of the base substrate 240. The metal bumps 272 are electrically coupled to corresponding contacts 244 through the ACF 270. One type of anisotropic adhesive suitable for forming the ACF 270 is known as a “z-axis anisotropic adhesive”. Z-axis anisotropic adhesives are filled with conductive particles 270a to a low level such that the particles do not contact each other in the xy plane. Therefore, compression of the material in the z direction establishes an electrical path between the metal bumps 272 and corresponding contacts 244 through the conductive particles 270a.

FIG. 5 shows a multi-chip module 500 according to a fourth preferred embodiment of the present invention. The multi-chip module 500 is characterized in that the lower surface of the base substrate 241 has a cavity 240b. The multi-chip module 500 further comprises a semiconductor chip 280 mounted inside the cavity 240b and electrically connected to a fourth set of contacts 248 formed in the cavity 240b. It could be understood that the base substrate 241 has electrically conductive lines (not shown) for providing electrical connection between the fourth set of contacts 248 and the third set of contacts 246. The semiconductor chip 280 is encapsulated in a third package body.

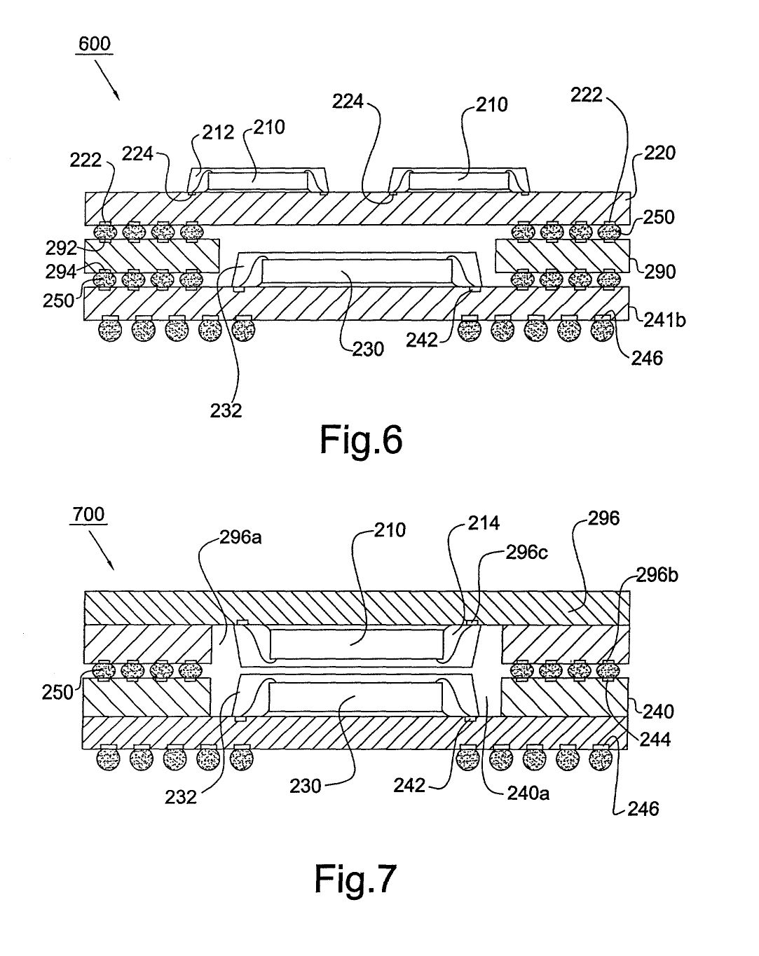

FIG. 6 shows a multi-chip module 600 according to a fifth preferred embodiment of the present invention. The multi-chip module 600 is characterized by having an intermediary substrate 290 interposed between an interconnection substrate 220 and a base substrate 241b wherein the intermediary substrate 290 has an opening for accommodating a semiconductor chip 230. The minimum distance between the interconnection substrate 220 and the base substrate 241b is greater than the maximum profile height of the package body 232 sealing the chip 230. It could be understood that the intermediary substrate 290 is provided with a set of intermediary pads 292 on the upper surface thereof, another set of intermediary pads 294 on the lower surface thereof and a plurality of electrically conductive lines (not shown) for providing electrical connection between the pads 292 and the pads 294. The intermediary substrate 290 is electrically coupled to the interconnection substrate 220 and the base substrate 241b through a plurality of solder balls 250. Alternatively, electrical connection therebetween may be provided by column-like solder bumps or anisotropic conductive adhesive film (ACF).

FIG. 7 shows a multi-chip module 700 according to a sixth preferred embodiment of the present invention. The multi-chip module 500 is characterized by having a upper chip 210 mounted inside a cavity 296a formed on an interconnection substrate 296 and a lower chip 230 mounted inside a cavity 240a formed on a base substrate 240. The lower surface of the interconnection substrate 296 is provided with a set of interconnection pads 296b formed outside the cavity 296a and another set of interconnection pads 296c formed inside the cavity 296a. It could be understood that a plurality of electrically conductive lines (not shown) are provided in the interconnection substrate 296 for providing electrical connection between the pads 296b and the pads 296c. It is noted that the interconnection substrate 296 is mounted on the upper surface of the base substrate 240 such that the minimum distance between the cavity 296 of the interconnection substrate 296 and the cavity 240a of the base substrate 240 is greater than the maximum profile height of the package body 232 and the package body 214.

The multi-chip module in accordance with the present invention can be mounted onto a substrate, such as a printed circuit board (PC board), through a plurality of solder balls. It could be understood that the third set of contacts 246 exposed from the bottom surface of the package can be printed with solder paste and then mounted onto the PC board.

In the multi-chip module of the present invention, the upper chip and the lower chip are packaged and tested separately before mounting the interconnection substrate to the base substrate. Therefore, the need for known good die (KGD) to manufacture the multi-chip module can be avoided, thereby significantly increasing resulting yield of the MCM in accordance with the present invention.

Although the invention has been explained in relation to its preferred embodiment, it is to be understood that many other possible modifications and variations can be made without departing from the spirit and scope of the invention as hereinafter claimed. For example, although only two-layer structure is illustrated as preferred embodiments, the multi-chip modules with three-layer structure or above are still considered within the spirit and scope of the invention.

What is claimed is:

1. A multi-chip module comprising:
a base substrate having opposing upper and lower surfaces, the upper surface of the base substrate having a first cavity, the base substrate including a first set of contacts formed inside the first cavity, a second set of contacts on the upper surface of the base substrate outside the first cavity, and a third set of contacts on the lower surface of the base substrate wherein the third set of contacts are electrically interconnected to the first set of contacts and the second set of contacts;
a first semiconductor chip mounted inside the first cavity of the base substrate and electrically connected to the first set of contacts wherein the first semiconductor chip is encapsulated in a first package body forming a maximum profile height;
an interconnection substrate mounted on the upper surface of the base substrate such that the minimum distance between the interconnection substrate and the first cavity of the base substrate is greater than the maximum profile height of the first package body, the interconnection substrate being provided with a set of interconnection pads on a lower surface thereof for electrically interconnecting to the second set of contacts;
a second semiconductor chip mounted on the interconnection substrate and electrically connected to the set of interconnection pads; and
a second package body encapsulating the second semiconductor chip.

2. The multi-chip module as claimed in claim 1, wherein the interconnection substrate is electrically interconnecting to the base substrate through a plurality of solder balls.

3. The multi-chip module as claimed in claim 1, wherein the interconnection substrate is electrically interconnecting to the base substrate through column-like solder bumps formed from stencil-printing.

4. The multi-chip module as claimed in claim 1, wherein the interconnection substrate is electrically interconnecting to the base substrate through an anisotropic conductive adhesive film (ACF).

5. The multi-chip module as claimed in claim 1, further comprising a second cavity formed in the lower surface of the base substrate, a fourth set of contacts formed in the second cavity and a third semiconductor chip mounted inside the second cavity and electrically connected to the fourth set of contacts wherein the third semiconductor chip is encapsulated in a third package body.

6. The multi-chip module as claimed in claim 1, further comprising a third cavity formed in the lower surface of the interconnection substrate wherein the second semiconductor chip is mounted inside the third cavity and the second package body forms a maximum profile height, and the interconnection substrate is mounted on the upper surface of the base substrate such that the minimum distance between the first cavity and the third cavity is greater than the maximum profile height of the first package body and the second package body.

7. A multi-chip module comprising:
a base substrate having opposing upper and lower surfaces, the upper surface of the base substrate being provided with a first set of contacts and a second set of contacts surrounding the first set of contacts, the lower surface of the base substrate being provided with a third set of contacts are electrically interconnected to the first set of contacts and the second set of contacts;
a first semiconductor chip mounted on the upper surface of the base substrate and electrically connected to the first set of contacts wherein the first semiconductor chip is encapsulated in a first package body forming a maximum profile height;
an interconnection substrate disposed above the upper surface of the base substrate and provided with a set of interconnection pads on a lower surface thereof;
a second semiconductor chip mounted on a upper surface of the interconnection substrate and electrically connected to the set of interconnection pads wherein the second semiconductor chip is encapsulated in a second package body; and
an intermediary substrate interposed between the interconnection substrate and the base substrate for electrically interconnecting the interconnection substrate to the base substrate, the intermediary substrate having an opening for accommodating the first semiconductor chip,
wherein the minimum distance between the interconnection substrate and the base substrate is greater than the maximum profile height of the first package body.

8. The multi-chip module as claimed in claim 7, wherein the interconnection substrate is electrically interconnecting to the base substrate through a plurality of solder balls.

9. The multi-chip module as claimed in claim 7, wherein the interconnection substrate is electrically interconnecting to the base substrate through column-like solder bumps formed from stencil-printing.

10. The multi-chip module as claimed in claim 7, wherein the interconnection substrate is electrically interconnecting to the base substrate through two anisotropic conductive adhesive films (ACFs).

11. The multi-chip module as claimed in claim 7, further comprising a cavity formed in the lower surface of the base substrate, a fourth set of contacts formed in the cavity and a third semiconductor chip mounted inside the cavity of the base substrate and electrically connected to the fourth set of contacts wherein the third semiconductor chip is encapsulated in a third package body.
